(19) United States
(12) Patent Application Publication
(10) Pub. No.: US 2010/0236820 A1
(43) Pub. Date: Sep. 23, 2010

(54) PREPREG HAVING UNIFORM PERMITTIVITY, AND METAL CLAD LAMINATES AND PRINT WIRING BOARD USING THE SAME

(75) Inventor: Sang Hyuk SUH, Daejeon-city (KR)

Correspondence Address: Nixon Peabody LLP, P.O. Box 60610, Palo Alto, CA, 94306, US

(73) Assignee: SAMSUNG FINE CHEMICALS CO., LTD, Ulsan-city (KR)

(21) Appl. No.: 12/675,960

(22) PCT Filed: Nov. 13, 2008
(86) PCT No.: PCT/KR2008/006692

§ 371 Date: Mar. 1, 2010

(30) Foreign Application Priority Data
Nov. 13, 2007 (KR) 10-2007-0115702
Nov. 13, 2007 (KR) 10-2007-0115703
Nov. 13, 2007 (KR) 10-2007-0115704

(51) Int. Cl. H05K 1/00; B32B 3/00

(52) U.S. Cl. 174/258; 428/141

(57) ABSTRACT

A prepreg, and a metal clad laminate and printed wiring board including the prepreg. The prepreg includes a substrate and a liquid crystal polymer resin impregnated into the substrate, and has a surface roughness in a range of 0.1 to 5.0 μm on one or both surfaces thereof.

### CROSS-REFERENCE TO RELATED PATENT APPLICATION

This application is a national phase International Application No. PCT/KR2008/006692, entitled, “Prepreg Having Uniform Permittivity, And Metal Clad Laminates And Print Wiring Board Using The Same”, which was filed on Nov. 13, 2008, and which claims priority of Korean Patent Application No. 10-2007-00115702, filed Nov. 13, 2007; Korean Patent Application No. 10-2007-00115703, filed Nov. 13, 2007; and Korean Patent Application No. 10-2007-00115704, filed Nov. 13, 2007, in the Korean Intellectual Property Office, the contents of which are incorporated herein by reference.

### BACKGROUND OF THE INVENTION

1. Technical Field

An embodiment of the present invention relates to a prepreg, and a metal clad laminate and printed wiring board including the prepreg, and more particularly, to a prepreg having uniform surface roughness, and a metal clad laminate and printed wiring board including the prepreg.

2. Background Art

According to recent miniaturization and multifunctionalization of electronic devices, high densification and miniaturization of printed wiring boards are currently being researched. Metal clad laminates are widely available materials that can be used as printed wiring boards for electronic devices due to their excellent stamping processability, drilling processability, and low cost.

A prepreg used in a metal clad laminate for a printed wiring board should have the following principal properties in order to be suitable for semiconductor performance and semiconductor package manufacturing conditions:

(1) a low thermal expansion rate in response to a metal (integrated circuit (IC) chip) thermal expansion rate;

(2) a low dielectric property and dielectric stability in a high frequency range of 1 GHz or more;

(3) heat resistance to a reflow process performed at around 270° C.

(4) uniform dielectric property of a prepreg in a horizontal direction (width and length direction);

(5) high adhesive property of a prepreg to a metal thin film.

In general, a prepreg is prepared by impregnating a glass fabric with a resin derived from epoxy or bismaleimidetriazine and then semi-hardening the resin. Then, a metal thin film is stacked on the prepreg and the resin is completely hardened to form a metal clad laminate. The metal clad laminate is formed to be a thin film and subjected to a high-temperature process, such as a reflow process performed at 270° C. By performing the high-temperature process, the metal clad laminate in the form of a thin film may be deformed due to a difference between thermal expansion rates of the prepreg and the metal thin film.

Also, high hygroscopicity of the resin derived from epoxy or bismaleimidetriazine should be decreased. In particular, dielectric properties of the resin are poor in a high frequency range of 1 GHz or more (that is, a high dielectric constant in a high frequency range), and thus it is difficult to apply such a resin to a printed wiring board for a semiconductor package, which requires a high-frequency and high-speed process. When the hygroscopicity of such a resin is high, problems, such as i) detachment of the resin from the prepreg caused by a change in a size of the prepreg including the resin according to moisture absorption of the resin, ii) warpage of the prepreg, and iii) blister occurrence in the prepreg caused by moisture evaporation during processing, such as a reflow process, occur.

To simplify manufacturing processes and shorten a manufacturing time by addressing problems, such as the deterioration of the dielectric properties and decreasing the time spent in hardening a resin, a prepreg may be prepared using a liquid crystal polymer resin, which has low dielectric properties in a high frequency range and is a thermoplastic. Such a prepreg is prepared by impregnating an organic or inorganic woven fabric with a liquid crystal polymer resin, and rolling and drying the resultant. In the rolling process, some of the liquid crystal polymer resin impregnated into the woven fabric is exuded to a surface of the woven fabric, thereby forming a resin layer. In this case, the woven fabric is adhered to the metal thin film, with the resin layer intervening therebetween.

In addition, the prepreg should have a small variation in a dielectric constant in a horizontal direction. If the variation in the dielectric constant in a horizontal direction of the prepreg is large, a short-circuit or another type of device malfunction may occur when the prepreg is used as a substrate, due to a non-uniform electric resistance of the prepreg.

### DESCRIPTION OF THE DRAWINGS

The above and other features and advantages of the present invention will become more apparent by describing in detail exemplary embodiments thereof with reference to the attached drawings in which:

FIG. 1 is a partial perspective view of a prepreg according to an embodiment of the present invention;

FIG. 2 is a cross-sectional view of a metal clad laminate including the prepreg of FIG. 1, according to an embodiment of the present invention;

FIG. 3 is a cross-sectional view of a metal clad laminate including a prepreg according to another embodiment of the present invention;

FIG. 4 is a cross-sectional view of a metal clad laminate including a prepreg according to another embodiment of the present invention;

FIG. 5 is a cross-sectional view of a printed wiring board including the prepreg of FIG. 1, according to an embodiment of the present invention; and

FIG. 6 is a cross-sectional view of a metal clad laminate including the printed wiring board of FIG. 5, according to an embodiment of the present invention.

### DETAILED DESCRIPTION OF THE INVENTION

### Technical Problem

An embodiment of the present invention provides a prepreg having a uniform surface roughness.

Another embodiment of the present invention also provides a prepreg having an optimized rate of resin impregnation.

Another embodiment of the present invention also provides a metal clad laminate and printed wiring board including the prepreg.

### Technical Solution

According to an aspect of the present invention, there is provided a prepreg comprising: a substrate; and a liquid crystal polymer resin that is impregnated into the substrate, wherein the prepreg has a surface roughness in a range of 0.1 to 5.0 μm on one or both surfaces thereof.

An impregnation rate of the liquid crystal polymer resin may be in a range of 44 to 52 wt % based on the total weight of the substrate and the liquid crystal polymer resin.

The prepreg may further comprise a liquid crystal polymer resin layer formed such that some of the liquid crystal polymer resin impregnated into the substrate is exuded to a surface of the substrate. In this regard, a thickness of the liquid crystal polymer resin layer may account for 9 to 23% of the total thickness of the substrate and the liquid crystal polymer resin layer.

The substrate may comprise at least one selected from the group consisting of a glass fiber fabric, a glass fiber woven fabric, a glass fiber non-woven fabric, and a carbon fiber fabric.

The liquid crystal polymer resin may comprise at least one selected from the group consisting of polyester, polyamide, polyimide, polyesteramide, polyesterimide, polyphosphazene, and polyazomethine.

The prepreg may have a relative dielectric constant of 4.0 or less in a high-frequency range of 1 GHz or more, and having a standard deviation in the relative dielectric constant of 0.1 or less.

According to another aspect of the present invention, there is provided a metal clad laminate comprising a prepreg or prepreg laminate formed such that at least two sheets of the prepreg are stacked, and a metal thin film disposed on one or both surfaces of the prepreg or the prepreg laminate.

The metal clad laminate may further comprise a liquid crystal polymer correction layer disposed between the prepreg and the metal thin film.

The liquid crystal polymer correction layer may be inserted, in the form of a film, between the prepreg and the metal thin film. The liquid crystal polymer correction layer may be formed by coating a surface of the prepreg or a surface of the metal thin film with a liquid crystal polymer resin varnish.

A thickness of the liquid crystal polymer correction layer may account for 5 to 30% of an average thickness of the prepreg.

A bond strength between the prepreg and the metal thin film adhered to the prepreg may be in a range of 0.5 to 2.5 N/mm.

According to another aspect of the present invention, there is provided a printed wiring board obtained by forming a circuit in the metal clad laminate.

According to another aspect of the present invention, there is provided a metal clad laminate comprising the printed wiring board, a prepreg or prepreg laminate that is disposed on at least one surface of the printed wiring board, and a metal thin film that is disposed on the prepreg or the prepreg laminate.

### Best Mode

Hereinafter, the present invention will be described more fully with reference to the accompanying drawings, in which exemplary embodiments of the invention are shown.

FIG. 1 is a partial perspective view of a prepreg 10 according to an embodiment of the present invention.

Referring to FIG. 1, the prepreg 10 according to the current embodiment of the present invention includes a substrate and a liquid crystal polymer resin impregnated into the substrate, although the substrate and the liquid crystal polymer resin are not separately illustrated in FIG. 1.

The substrate may be a glass fiber fabric, a glass fiber woven fabric, a glass fiber non-woven fabric and/or a carbon fiber fabric. Desirably, the substrate may be the glass fiber woven fabric due to benefits in terms of mechanical and electrical characteristics, and from an economical point of view.

The liquid crystal polymer resin may be any type of liquid crystal polymer resin that can be dissolved in a solvent. For example, the liquid crystal polymer resin may be thermotropic aromatic liquid crystal polyester that can form a molten product having optical anisotropy at 400° C. or lower. For example, a melting point of the aromatic liquid crystal polyester may be in a range of 280-400° C. When the melting point thereof is less than 280° C., a soldering temperature of a printed wiring board in the subsequent substrate treatment process is higher than the melting point, and thus the substrate may be deformed. On the other hand, when the melting point thereof is greater than 400° C., a high-temperature process is required in the subsequent stacking process, and the solubility of the polymer with respect to the solvent is decreased. In addition, a number average molecular weight of the aromatic liquid crystal polyester may be in a range of 1,000 to 20,000. When the number average molecular weight of the aromatic liquid crystal polyester is less than 1,000, mechanical strength of the prepreg is insufficient. On the other hand, when the number average molecular weight of the aromatic liquid crystal polyester is greater than 20,000, solubility of the polymer with respect to the solvent may be decreased.

A concentration of a liquid crystal polymer resin solution may be in a range of 1-40 wt %, for example, 10-30 wt %, and for example, 15-25 wt %. When the concentration of the liquid crystal polymer resin solution is less than 1 wt %, the amount of a liquid crystal polymer resin that can be impregnated into a substrate in a one-time process is small, and thus productivity of the prepreg may be decreased. On the other hand, when the concentration of the liquid crystal polymer resin solution is greater than 40 wt %, the viscosity of the liquid crystal polymer resin solution is increased, and thus it is difficult to impregnate the resin solution to the substrate during prepreg processing.

The solvent used to dissolve the liquid crystal polymer resin may be a non-halogen solvent, but is not limited thereto. For example, the solvent may be a polar non-proton based compound, halogenated phenol, o-dichlorobenzene, chloroform, methylene chloride, tetrachloroethane, or at least two of these compounds. In particular, the liquid crystal polymer resin that is dissolved even in the non-halogen solvent does not need to use a halogen element-containing solvent. Thus, during and after an impregnation process, a metal thin film of a metal clad laminate or printed wiring board can be prevented from being corroded due to a halogen element, while the metal film can be corroded in the case of using the halogen element-containing solvent.

In preparing the prepreg, a composition solution formed such that the liquid crystal polymer resin is dissolved in the solvent may be impregnated into the substrate for, in general, 0.02 minutes to 10 minutes. When the impregnating time is less than 0.02 minutes, the liquid crystal polymer resin cannot be uniformly impregnated. On the other hand, when the impregnating time is greater than 10 minutes, the productivity may be decreased.

In addition, the composition solution formed such that the liquid crystal polymer resin is dissolved in the solvent may be impregnated into the substrate at a temperature in a range of 20 to 190° C., for example at room temperature.

Without departing from the scope of the present invention, the composition solution formed such that the liquid crystal polymer resin is dissolved in the solvent may further include an inorganic filler, such as silica, aluminum hydroxide, or calcium carbonate; or an organic filler, such as cured epoxy resin or crosslinked acrylic resin, in order to control a dielectric constant and a thermal expansion rate. The amount of the inorganic filler or organic filler added may be in a range of 0.5-200 parts by weight with respect to 100 parts by weight of the liquid crystal polymer resin. When the amount of the inorganic filler or organic filler is less than 0.5 parts by weight with respect to 100 parts by weight of the liquid crystal polymer resin, it is difficult to sufficiently decrease the dielectric constant or the thermal expansion rate of the prepreg 10. On the other hand, when the amount of the inorganic filler or organic filler is greater than 200 parts by weight with respect to 100 parts by weight of the liquid crystal polymer resin, the binding effect of the liquid crystal polymer resin may be decreased.

The prepreg 10 is prepared by impregnating or coating the substrate with the composition solution prepared by dissolving the liquid crystal polymer resin in the solvent, and then drying and rolling the resultant. The drying and rolling processes may be sequentially performed, and may also be simultaneously performed. The solvent included in the prepreg 10 is removed by the drying process, and the rolling process is performed on the prepreg 10 to have a desired thickness and surface roughness 10a. The rolling process may be performed, for example, at a press roller temperature of 120° C. at a press roller pressure of 10 kgf/cm², and in a condition where the temperature of the prepreg 10 is 300° C. In this case, the surface roughness 10a of the prepreg 10 is controlled by a surface roughness of the press roller. In addition, a removing process of the solvent is not particularly limited, but may be performed by, for example, solvent evaporation, such as heat evaporation, vacuum evaporation, or ventilation evaporation. Specifically, use of the heat evaporation, more specifically the ventilation & heat evaporation, is desirable in terms of applicability to a conventional prepreg manufacturing process, production efficiency, and handling convenience.

In the process of removing the solvent, the composition solution of the liquid crystal polymer resin may be pre-dried at a temperature in a range of 20 to 190° C. for 1 minute to 10 minutes, and then the resultant composition solution is heat treated at a temperature in a range of 190 to 350° C. for 1 minute to 10 hours.

The prepared prepreg 10 according to the present embodiment has a surface roughness 10a of 0.1 to 5.0 μm on one or both surfaces thereof. The surface roughness 10a may occur on a surface of the substrate. Alternatively, as illustrated in FIG. 3, the surface roughness 10a may be formed on a surface of a liquid crystal polymer resin layer 12 formed such that some of the liquid crystal polymer resin impregnated into a substrate 11 is exuded to a surface of the substrate 11. When the surface roughness 10a occurs on the surface of the substrate, an adhesive agent may be further intervened between the prepreg and a metal thin film when a metal clad laminate is formed. Since the prepreg 10 has the surface roughness 10a, a bond strength between the surface of the prepreg 10 and the metal thin film is increased. Due to the increased bond strength, even when the metal thin film is thermally expanded due to a high-temperature treatment during the subsequent processing of a substrate of a printed wiring board, thermal deformation in which the metal thin film is detached from the surface of the prepreg can be prevented from occurring. When the surface roughness is less than 0.1 μm, the bond strength between the surface of the prepreg and the metal thin film is insufficient. On the other hand, when the surface roughness is greater than 5.0 μm, voids are locally formed between the prepreg and the metal thin film, and thus a variation in a dielectric constant in a horizontal direction is increased, and defects, such as blisters, may occur.

In addition, the thickness of the prepreg may be in the range of about 5 to 200 μm, for example in the range of about 30 to 150 μm. The prepreg may have a relative dielectric constant of 4.0 or less in a high frequency range of 1 GHz or more, and may have a standard deviation in the relative dielectric constant of 0.1 or less. When the relative dielectric constant of the prepreg is greater than 4.0, the prepreg may not be suitable for use as an insulating substrate in a high frequency range.

Since the prepreg according to the present embodiment includes the liquid crystal polymer resin having a low hygroscopicity and low dielectric properties and an organic or inorganic woven and/or non-woven fabric having excellent mechanical strength, the prepreg has excellent dimensional stability, is difficult to be deformed, and is hard. Due to these characteristics, the prepreg is suitable for via-hole drilling and stacking processing.

Also, a prepreg laminate may be prepared by stacking a predetermined number of the prepregs and then heating and compressing the stacked prepregs.

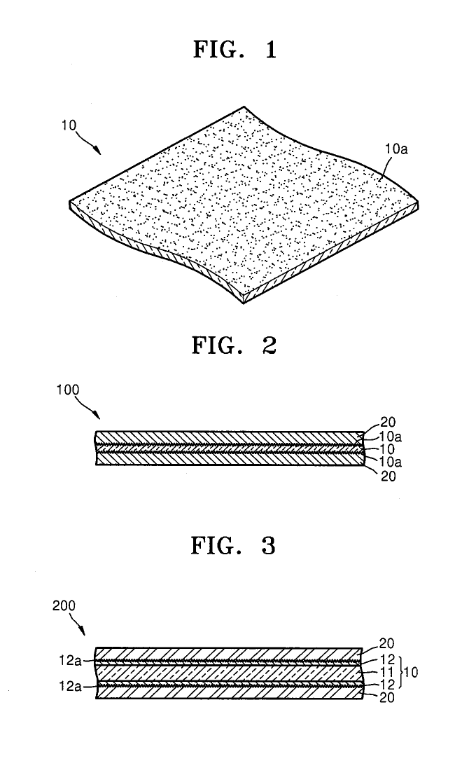

FIG. 2 is a cross-sectional view of a metal clad laminate 100 including the prepreg 10 of FIG. 1, according to an embodiment of the present invention. Hereinafter, like reference numerals in the drawings denote like elements or a portion of the like elements.

The metal clad laminate 100 according to the present embodiment includes the prepreg 10 and metal thin films 20 disposed on both surfaces of the prepreg 10. In addition, the prepreg 10 includes the substrate (not shown) and the liquid crystal polymer resin impregnated into the substrate (not shown).

The prepreg 10 has surface roughnesses 10a formed on both surfaces thereof. The size and technical effect of the surface roughnesses 10a are the same as described above, and thus a detailed description thereof will not be provided here.

As described above, the prepreg 10 has the surface roughness 10a on one or both surfaces thereof, and thus the bond strength between the prepreg 10 and the metal thin films 20 adhered thereto may be, for example, in a range of 0.5 to 2.5 N/mm. When the bond strength is less than 0.5 N/mm, the metal thin films 20 may be detached from the prepreg 10 due to deformation caused by a thermal and mechanical external force during processing of a printed wiring board. On the other hand, when the bond strength is greater than 2.5 N/mm, a lot of time may be required to perform etching and stripping.

The metal clad laminate 100 may be prepared by disposing the metal thin film 20, such as a copper film, a silver film, or an aluminum film, on at least one surface of the prepreg 10 or the prepreg laminate prepared by stacking a predetermined number of the prepregs 10, and then heating and compressing the resultant structure. In the metal clad laminate 100, the thickness of the prepreg 10 or the prepreg laminate, and the thickness of the metal thin film 20 may be, but is not limited to, in a range of 30 to 200 μm and in a range of 1 to 50 μm, respectively. When the thickness of the prepreg 10 or prepreg laminate is less than 30 μm, the prepreg 10 or prepreg laminate may crack due to deficient mechanical strength when a rolling process is performed thereon. On the other hand, when the thickness of the prepreg 10 or prepreg laminate is greater than 200 μm, the number of prepregs that can be stacked is limited. When the thickness of the metal thin film 20 is less than 1 μm, the metal thin film 20 may crack when the metal film 20 is stacked on the prepreg 10 or prepreg laminate. On the other hand, when the thickness of the metal thin film 20 is greater than 50 μm, the number of prepregs that can be stacked is limited.

In preparing the metal clad laminate 100, the heating and compressing process may be performed at a temperature in a range of 250 to 400° C. at a pressure in a range of 5 to 100 Kgf/cm². However, the heating temperature and the compressing pressure are not limited thereto. That is, the heating temperature and the compressing pressure may be appropriately determined, taking into consideration characteristics of the prepreg 10, reactivity of the liquid crystal polymer resin composition, a performance of a pressing device, a desired thickness of the metal clad laminate 100, or the like.

FIG. 3 is a cross-sectional view of a metal clad laminate 200 including a prepreg according to another embodiment of the present invention.

The metal clad laminate 200 according to the present embodiment includes a prepreg 10 and metal thin films 20 disposed on both surfaces of the prepreg 10. In addition, the prepreg 10 includes a substrate 11, a liquid crystal polymer resin impregnated into the substrate 11 (not shown), and liquid crystal polymer resin layers 12 that are formed such that some of the liquid crystal polymer resin is exuded to both surfaces of the substrate 11.

Surface roughnesses 12a may be formed on one or both surfaces of the prepreg 10, in particular, on surfaces of the liquid crystal polymer resin layers 12 that are formed on one or both surfaces of the substrate 11. The formation of the surface roughnesses 12a and the size and technical effect thereof are the same as described in the surface roughnesses 10a described above. Thus, a detailed description thereof will not be provided here.

In the present embodiment, an impregnation rate of the liquid crystal polymer resin is adjusted to obtain the liquid crystal polymer resin layers 12 having a thickness within an appropriate range, and the surface roughnesses 12a are respectively formed on the surfaces of the liquid crystal polymer resin layers 12. In this regard, the liquid crystal polymer resin layers 12 function as an adhesive medium, and thus the bond strength between the prepreg 10 and the metal thin films 20 is further increased.

A rate in which the liquid crystal polymer resin is impregnated into the substrate 11 (that is, an impregnation rate) may be in a range of 44 to 52 wt % based on the total weight of the substrate 11 and the liquid crystal polymer resin. When the impregnation rate is less than 44 wt % based on the total weight of the substrate 11 and the liquid crystal polymer resin, the amount of liquid crystal polymer resin impregnated into the substrate 11 is insufficient, and thus the liquid crystal polymer resin layers 12 are not formed at all or are not formed to a sufficient thickness. Therefore, when the metal thin films 20 are stacked on the substrate 11, the metal thin films 20 directly contact the substrate 11 without an adhesive medium, or the substrate 11 contacts the metal thin films 20, with the too thin liquid crystal polymer resin layers 12 intervening therebetween, and thus the bond strength therebetween may be decreased. In addition, due to the decreased bond strength, the metal thin films 20 may easily migrate on the surface of the substrate 11. On the other hand, when the impregnation rate is greater than 52 wt % based on the total weight of the substrate 11 and the liquid crystal polymer resin, the liquid crystal polymer resin layers 12 are too thick, and thus the liquid crystal polymer resin layers 12 may crack, resulting in a decrease in the bond strength between the substrate 11 and the metal thin films 20. An appropriate thickness of the liquid crystal polymer resin layers 12 may be in a range of 9 to 23 wt % based on the total weight of the substrate 11 and the liquid crystal polymer resin layers 12.

In addition, the metal clad laminate 200 according to the present embodiment may no longer require an adhesive layer that is interposed between the prepreg 10 and the metal thin films 20, wherein the adhesive layer is used to increase the bond strength between the prepreg 10 and the metal thin films 20. Accordingly, manufacturing processes can be simplified and manufacturing costs can be reduced.

FIG. 4 is a cross-sectional view of a metal clad laminate 300 including a prepreg according to another embodiment of the present invention.

Referring to FIG. 4, the metal clad laminate 300 according to the present embodiment includes a prepreg 10, metal thin films 20, and liquid crystal polymer correction layers 30.

The prepreg 10 includes a substrate 11 and liquid crystal polymer resin layers 12. Although not illustrated in FIG. 4, a liquid crystal polymer resin is impregnated into the substrate 11. Some of the liquid crystal polymer resin is exuded to the surfaces of the substrate 11 to form the liquid crystal polymer resin layers 12 having the form of a plurality of islands. In the present embodiment, the liquid crystal polymer resin layers 12 partially cover the surfaces of the substrate 11, and a plurality of protrusions 11a of the substrate 11 are formed on the surfaces that are not covered by the liquid crystal polymer resin layers 12. However, the present invention is not limited thereto, and the liquid crystal polymer resin layers 12 may entirely cover the substrate 11. The prepreg 10 according to the present embodiment is prepared, in general, by performing an impregnating process three times or less, but the present invention is not limited thereto.

The liquid crystal polymer correction layers 30 are formed on the substrate 11 to cover the liquid crystal polymer resin layers 12 and the protrusions 11a of the substrate 11, and the liquid crystal polymer correction layer 30 has a surface roughness 30a on a surface thereof. The formation of the surface roughness 30a and the size and technical effect thereof are the same as described in relation to the surface roughness 10a above. Thus, a detailed description thereof will not be provided here.

The liquid crystal polymer correction layers 30 have two main functions. One is to function as an adhesive medium that increases the bond strength between the prepreg 10 and the metal thin films 20. The other is to provide the metal thin films 20 with smooth coated surfaces such that the liquid crystal polymer correction layers 30 entirely cover the surfaces of the prepreg 10 having uneven shapes on which the liquid crystal polymer resin layers 12 having the form of the plurality of islands and the protrusions 11a of the substrate 11 coexist. In particular, when the liquid crystal polymer resin layers 12 included in the prepreg 10 do not completely cover the surfaces of the substrate 11, the liquid crystal polymer correction layers 30 cover the surfaces of the substrate 11 that are not covered by the liquid crystal polymer resin layers 12, thereby increasing the bond strength between the prepreg 10 and the metal thin films 20, wherein the liquid crystal polymer correction layers 30 includes a liquid crystal polymer resin that is the same or similar to the liquid crystal polymer resin of the liquid crystal polymer resin layers 12. In addition, the liquid crystal polymer correction layers 30 correct the rough surfaces of the prepreg 10, thereby helping the metal thin films 20 being stacked on the prepreg 10, with the metal thin films maintaining its original uniform surface state without deformation.

Meanwhile, if the thickness of the liquid crystal polymer resin layers 12 is not thick enough to obtain a desired bond strength between the prepreg 10 and the metal thin films 20 even when a considerably large amount of the impregnated liquid crystal polymer resin is exuded to the surfaces of the substrate 11 to entirely cover the substrate 11, the liquid crystal polymer correction layers 30 may be disposed to cover the liquid crystal polymer resin layers 12.

The liquid crystal polymer correction layers 30 may be inserted in the form of a film between the prepreg 10 and the metal thin films 20. Alternatively, the liquid crystal polymer correction layers 30 may be formed by coating a surface of the prepreg 10, that is, a surface of the prepreg 10 facing the metal thin film 20 with a liquid crystal polymer resin varnish, or by coating a surface of the metal thin film 20, that is, a surface of the metal thin film 20 facing the prepreg 10 with a liquid crystal polymer resin varnish.

An appropriate thickness of the liquid crystal polymer correction layers 30 may be in a range of 5 to 30% based on an average thickness of the prepreg 10. When the thickness of the the liquid crystal polymer correction layers 30 is less than 5% based on an average thickness of the prepreg 10, the metal thin films 20 may directly contact the liquid crystal polymer resin layers 12, and thus it is difficult to obtain a high bond strength between the prepreg 10 and the metal thin films 20. On the other hand, when the thickness of the the liquid crystal polymer correction layers 30 is greater than 30% based on an average thickness of the prepreg 10, a total thickness of the metal clad laminate 300 is large when the metal thin films 20 are stacked on the liquid crystal polymer correction layers 30, and thus it is difficult to obtain a metal clad laminate 300 that is light, thin, short, and small.

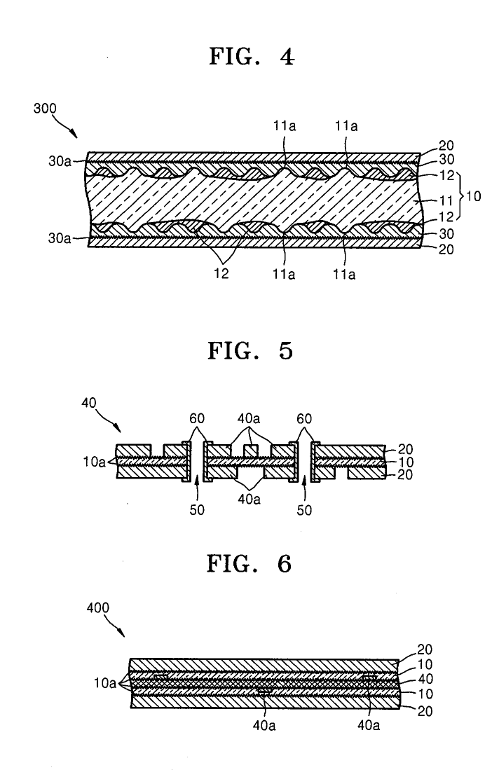

FIG. 5 is a cross-sectional view of a printed wiring board 40 including the prepreg of FIG. 1, according to an embodiment of the present invention.

Referring to FIG. 5, the printed wiring board 40 according to the present embodiment includes the prepreg 10 having the surface roughnesses 10a formed on both surfaces thereof and the metal thin films 20. The printed wiring board 40 may be prepared by positioning the metal thin films 20 on both surfaces of the prepreg 10, heating and compressing the resultant, and then forming circuits 40a in the metal thin films 20. The circuits 40a may be formed using conventional known methods, such as a subtractive process. In addition, through holes 50, which penetrate through the prepreg 10 and the metal thin films 20, are formed in the printed wiring board 40, and metal plating layers 60 are formed on inner walls of the through holes 50. In addition, the printed wiring board 40 is normally equipped with predetermined circuit components (not shown).

FIG. 6 is a cross-sectional view of a metal clad laminate 400 including the printed wiring board 40 of FIG. 5, according to an embodiment of the present invention.

Referring to FIG. 6, the metal clad laminate 400 according to the present embodiment includes the printed wiring board 40 in which the circuits 40a is formed, the prepregs 10 each having the surface roughness 10a, and the metal thin films 20. For example, the metal clad laminate 400 includes two sheets of the prepregs 10 that are respectively stacked on both surfaces of the printed wiring board 40 and two sheets of the metal thin films 20 that are respectively stacked on outer surfaces of the prepregs 10. Alternatively, the circuits 40a may be formed only on a surface of the printed wiring board 40. Also, the metal clad laminate 400 may include, between the prepreg 10 and the printed wiring board 40, at least one set of a laminated structure in which at least a separate printed wiring board and at least a separate prepreg are alternately stacked. In addition, the metal thin films may include a resin layer adhered to a surface of the metal thin film 20, facing the prepreg 10. In this case, the surface roughness is formed on a surface of the resin layer instead of the surface of the prepreg, that is, the surface of the resin layer, facing the metal thin film.

In the metal clad laminate including the prepreg having the structures described above, the bond strength between the prepreg and the metal thin films is increased, and accordingly, thermal deformation that causes the detachment of the metal thin films from the prepreg does not occur even when the metal clad laminate is exposed to a high temperature during metal clad laminate manufacturing. In addition, in the printed wiring board including the prepreg, a variation in a relative dielectric constant in a horizontal direction of the prepreg included in the printed wiring board is so small that a short-circuit or another device malfunction due to a non-uniform electric resistance of the prepreg can be prevented when the printed wiring board is used as a substrate. Moreover, the printed wiring board including the prepreg may have low dielectric properties in a high-frequency range.

The present invention will be described in further detail with reference to the following examples. These examples are for illustrative purposes only and are not intended to limit the scope of the present invention.

### EXAMPLE

### Example 1-1

Preparation of Prepreg

<Selection of Substrate>

A glass fiber fabric (IPC 2116) having a thickness of 100 μm and a weight per unit area of 107 g/m² was used as a substrate for preparing a prepreg.

<Preparation of Liquid Crystal Polymer Resin Varnish>

100 parts by weight of aromatic polyesteramide (number average molecular weight of 10,000) as a liquid crystal polymer resin and 400 parts by weight of n-methylpyrrolidone as a solvent were mixed together, and the mixture was then stirred at room temperature to prepare a liquid crystal polymer resin varnish.

<Preparation of Prepreg>

An impregnation container was filled with the liquid crystal polymer resin varnish, and then the substrate was inserted to the container to be impregnated with the liquid crystal polymer resin varnish. Then, the resultant was dried in a forced convection oven at 100° C. for 3 minutes to prepare a prepreg in which an impregnation amount of the liquid crystal polymer resin is 100 g/m². To adjust the surface roughness of the dried prepreg, the prepreg was heated to 300° C. using an infrared heater, and rolling was performed on the prepreg using a roller having a surface roughness (Ra) of 3 μm. The rolling process was performed on the prepreg at a roller temperature of 80° C. at a roller pressure of 10 Kgf/cm².

### Example 1-2

Preparation of Prepreg

A prepreg was prepared in the same manner as in Example 1-1, except that a roller having a surface roughness (Ra) of 0.5 μm was used in the rolling process.

### Example 1-3

Preparation of Prepreg

The liquid crystal polymer resin varnish prepared in Example 1-1 was coated on both surfaces of the prepreg prepared in Example 1-1 by using a knife coating method to have a thickness of 10 μm, and then the resultant was dried in a forced convection oven at 100° C. for 3 minutes to prepare a prepreg to which liquid crystal polymer correction layers were introduced. Subsequently, to adjust the surface roughness of the dried prepreg, the prepreg was heated to 300° C. using an infrared heater, and rolling was performed on the prepreg using a roller having a surface roughness (Ra) of 3 μm. The rolling process was performed on the prepreg at a roller temperature of 80° C. at a roller pressure of 10 Kgf/cm².

### Example 2-1

Preparation of Metal Clad Laminate

A metal clad laminate having the structure illustrated in FIG. 3 was prepared as follows.

Electrolytic copper foils having a thickness of 12 μm were respectively positioned on both surfaces of the prepreg of Example 1-1, and the resultant was compressed by using a hot press at 300° C. at 40 kgf/cm² to prepare a metal clad laminate.

### Example 2-2

Preparation of Metal Clad Laminate

A metal clad laminate was prepared in the same manner as in Example 2-1, except that the prepreg prepared in Example 1-2 was used.

### Example 2-3

Preparation of Metal Clad Laminate

A metal clad laminate was prepared in the same manner as in Example 2-1, except that the prepreg prepared in Example 1-3 to which the liquid crystal polymer correction layers were introduced was used.

### Comparative Example 1-1

Preparation of Prepreg

A prepreg was prepared in the same manner as in Example 1-1, except that a roller having a surface roughness (Ra) of 10 μm was used in the rolling process.

### Comparative Example 2-1

Preparation of Metal Clad Laminate

A metal clad laminate was prepared in the same manner as in Example 2-1, except that the prepreg prepared in Comparative Example 1-1 was used.

### Evaluation Test

Relative dielectric constants of the prepregs of Examples 1-1 through 1-3 and Comparative Examples 1-1 were measured, and the results are shown in Table 1 below. The relative dielectric constants thereof were measured in accordance with an IPC-TM-650 2.2.17A method. In particular, the measurement of the relative dielectric constants was performed on 9 points (upper-left, middle-left, lower-left, upper-middle, middle-middle, lower-middle, upper-right, middle-right, lower-right) of each of the prepreg samples at 1 GHz by using an Agilent Impedance/Material Analyzer, and includes calculating the average value and standard deviation of the relative dielectric constants.

TABLE 1

| | | | | Comparative |
|---|---|---|---|---|
| | Example 1-1 | Example 1-2 | Example 1-3 | Example 1-1 |
| | Surface | Surface | Surface | Surface |
| | roughness = | roughness = | roughness = | roughness = |
| | 3 μm | 0.5 μm | 3 μm | 10 μm |
| Average value | 3.17 | 2.95 | 3.25 | 3.43 |
| of relative | | | | |
| dielectric | | | | |
| constant | | | | |
| (at 1 GHz) | | | | |
| Standard | 0.042 | 0.027 | 0.033 | 0.16 |
| deviation of | | | | |
| relative | | | | |
| dielectric | | | | |
| constant | | | | |
| (at 1 GHz) | | | | |

In addition, with respect to the metal clad laminates of Examples 2-1 through 2-3 and Comparative Example 2-1, a peel strength (i.e., bond strength) between the copper foil and the prepreg was measured. The results are shown in Table 2 below. The measurement of the peel strength was performed in accordance with an IPC-TM-650 2.4.8 method.

TABLE 2

| | | | | Comparative |
|---|---|---|---|---|
| | Example 2-1 | Example 2-2 | Example 2-3 | Example 2-1 |
| Peel strength | 0.65 | 0.93 | 1.11 | 0.47 |
| (N/mm) | | | | |

In addition, surface states of the metal clad laminates of Examples 2-1 through 2-3 and Comparative Example 2-1 were observed by the naked eye, and the results are shown in Table 3 below.

TABLE 3

| | | | | Comparative |
|---|---|---|---|---|
| | Example 2-1 | Example 2-2 | Example 2-3 | Example 2-1 |
| Surface state | Δ | Δ | ◯ | X |

◯: no blister and smooth surface
Δ: no blister, but not smooth surface
X: blister occurrence

Referring to Tables 1 through 3, the prepregs of Examples 1-1 through 1-3 have a very small variation in the relative dielectric constant, compared with that of the prepreg of Comparative Example 1-1. In addition, the metal clad laminates of Examples 2-1 through 2-3 exhibit a very high peel strength (i.e., bond strength) between the copper foil and the prepreg, compared with that in the metal clad laminate of Comparative Example 2-1. Moreover, the surface state of the metal clad laminate of Example 2-3 to which the liquid crystal polymer correction layer was introduced is relatively good, compared with the surface states of the metal clad laminates of Examples 2-1 and 2-2 and Comparative Example 2-1 to which the liquid crystal polymer correction layers were not introduced.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A prepreg comprising:
a substrate; and
a liquid crystal polymer resin that is impregnated into the substrate,
wherein the prepreg has a surface roughness in a range of 0.1 to 5.0 μm on one or both surfaces thereof.

2. The prepreg of claim 1, wherein an impregnation rate of the liquid crystal polymer resin is in a range of 44 to 52 wt % based on the total weight of the substrate and the liquid crystal polymer resin.

3. The prepreg of claim 1, further comprising a liquid crystal polymer resin layer formed such that some of the liquid crystal polymer resin impregnated into the substrate is exuded to a surface of the substrate.

4. The prepreg of claim 3, wherein a thickness of the liquid crystal polymer resin layer accounts for 9 to 23% of the total thickness of the substrate and the liquid crystal polymer resin layer.

5. The prepreg of claim 1, wherein the substrate comprises at least one selected from the group consisting of a glass fiber fabric, a glass fiber woven fabric, a glass fiber non-woven fabric, and a carbon fiber fabric.

6. The prepreg of claim 1, wherein the liquid crystal polymer resin comprises at least one selected from the group consisting of polyester, polyamide, polyimide, polyesteramide, polyesterimide, polyphosphazene, and polyazomethine.

7. The prepreg of claim 1, having a relative dielectric constant of 4.0 or less in a high-frequency range of 1 GHz or more, and having a standard deviation in the relative dielectric constant of 0.1 or less.

8. A metal clad laminate according to claim 1, formed such that at least two sheets of the prepreg are stacked, and a metal thin film disposed on one or both surfaces of the prepreg or the prepreg laminate.

9. The metal clad laminate of claim 8, further comprising a liquid crystal polymer correction layer disposed between the prepreg and the metal thin film.

10. The metal clad laminate of claim 9, wherein the liquid crystal polymer correction layer is inserted, in the form of a film, between the prepreg and the metal thin film.

11. The metal clad laminate of claim 9, wherein the liquid crystal polymer correction layer is formed by coating a surface of the prepreg or a surface of the metal thin film with a liquid crystal polymer resin varnish.

12. The metal clad laminate of claim 9, wherein a thickness of the liquid crystal polymer correction layer accounts for 5 to 30% of an average thickness of the prepreg.

13. The metal clad laminate of claim 8, wherein a bond strength between the prepreg and the metal thin film adhered to the prepreg is in a range of 0.5 to 2.5 N/mm.

14. A printed wiring board obtained by forming a circuit in the metal clad laminate according to claim 8.

15. A metal clad laminate comprising a printed wiring board according to claim 14, a prepreg or prepreg laminate that is disposed on at least a surface of the printed wiring board, and a metal thin film that is disposed on the prepreg or the prepreg laminate.
